(19) United States
(12) Patent Application Publication
(10) Pub. No.: US 2026/0301628 A1
(43) Pub. Date: Oct. 1, 2026

(54) SHIFT REGISTER AND DISPLAY PANEL

(71) Applicant: Beijing Visionox Technology Co., Ltd., Beijing (CN)

(72) Inventors: Enqing GUO, Beijing (CN); Cuili GAI, Beijing (CN); Xiaoyang JIN, Beijing (CN); Jianjun LU, Beijing (CN); Shuang GUO, Beijing (CN)

(73) Assignee: Beijing Visionox Technology Co., Ltd., Beijing (CN)

(21) Appl. No.: 19/698,770

(22) Filed: Jun. 4, 2026

(30) Foreign Application Priority Data
Jun. 26, 2025 (CN) 202510873629.5

(51) Int. Cl. G09G 3/20; G11C 19/28

(52) U.S. Cl. CPC G09G 3/20; G11C 19/28; G09G 2310/0286; G09G 2310/08

(57) ABSTRACT

The present disclosure discloses a shift register and a display panel. The shift register includes a first signal output module and a second signal output module. A control terminal of the first signal output module and a first control terminal of the second signal output module are connected at a first node. The first node is configured to receive a start signal. A second control terminal of the second signal output module and an output terminal of the first signal output module are connected at a second node. The first signal output module is configured to output a first gate driving signal to the second node based on a voltage of the first node. The second signal output module is configured to output a second gate driving signal based on the voltage of the first node and a voltage of the second node.

### CROSS REFERENCE TO RELATED APPLICATIONS

This application claims priority to Chinese Patent Application No. 202510873629.5, filed on Jun. 26, 2025, entitled “Shift register and display panel,” which is incorporated herein by reference in its entirety.

### FIELD

Embodiments of the present disclosure relate to the field of display technology, and in particular, it relates to a shift register and a display panel.

### BACKGROUND

With the development of display technology, users have increasingly higher requirements for the display effect of display panels.

A display panel typically includes shift registers that provide gate driving signals for pixel circuits at various stages. Existing shift registers are relatively complex, which is not conducive to achieving a narrow bezel.

### SUMMARY

Embodiments of the present disclosure provide a shift register and a display panel to reduce the bezel of the display panel.

According to an aspect of the present disclosure, a shift register is provided, including: a first signal output module and a second signal output module. A control terminal of the first signal output module and a first control terminal of the second signal output module are connected at a first node. The first node is configured to receive a start signal. A second control terminal of the second signal output module and an output terminal of the first signal output module are connected at a second node. The first signal output module is configured to output a first gate driving signal to the second node based on a voltage of the first node. The second signal output module is configured to output a second gate driving signal based on the voltage of the first node and the voltage of the second node; and a short pulse width level of the first gate driving signal is opposite to a short pulse width level of the second gate driving signal.

According to another aspect of the present disclosure, a shift register is provided, including a second signal output module and a first potential control module; a first control terminal of the second signal output module and an output terminal of the first potential control module are connected at a first node. The first node is used for receiving a start signal. A second control terminal of the second signal output module and a first control terminal of the first potential control module are connected at a second node. The first potential control module is used for controlling a voltage of the first node based on a voltage of the second node. The second signal output module is used for outputting a second gate drive signal based on the voltage of the first node and the voltage of the second node. According to another aspect of the present disclosure, a display panel is provided, the display panel including a gate drive circuit. The gate drive circuit includes a plurality of shift registers according to any embodiment of the present disclosure. The plurality of shift registers are connected in cascade; in the plurality of cascaded shift registers, the start signal received by a next-stage shift register is provided by an output terminal of the second signal output module of a current-stage shift register. The start signal of a first-stage shift register is provided by a trigger signal line. In one embodiment provided by the embodiments of the present disclosure, by controlling the voltage of the first node, the first signal output module outputs a first gate drive signal to the second node based on the voltage of the first node, and the second signal output module outputs a second gate drive signal based on the voltage of the first node and the voltage of the second node. The first node is used for receiving a start signal, the second node is used for outputting the first gate drive signal, and a short pulse width level of the first gate drive signal is opposite to a short pulse width level of the second gate drive signal. Compared with solutions in the related art, the embodiments provided by this embodiment, through mutual borrowing and coordinated cooperation between the first signal output module and the second signal output module, can output two different types of gate drive signals, and has a simple circuit structure, which is beneficial for compressing the bezel of the display panel and achieving a narrow bezel design. The content described in this section is not intended to identify key or important features of the embodiments of the present disclosure, nor is it intended to limit the scope of the present disclosure. Other features of the present disclosure will become readily apparent from the following description.

### BRIEF DESCRIPTION OF THE DRAWINGS

To more clearly illustrate the embodiments of the present disclosure, the accompanying drawings required for describing the embodiments are briefly introduced below. In one embodiment, the drawings in the following description are only some embodiments of the present disclosure.

FIG. 1 is a schematic structural diagram of a shift register provided by an embodiment of the present disclosure;

FIG. 2 is a schematic structural diagram of another shift register provided by an embodiment of the present disclosure;

FIG. 3 is a schematic waveform diagram of a gate drive signal provided by an embodiment of the present disclosure;

FIG. 4 is a schematic structural diagram of another shift register provided by an embodiment of the present disclosure;

FIG. 5 is a schematic structural diagram of another shift register provided by an embodiment of the present disclosure;

FIG. 6 is a schematic structural diagram of another shift register provided by an embodiment of the present disclosure;

FIG. 7 is a schematic structural diagram of another shift register provided by an embodiment of the present disclosure;

FIG. 8 is a schematic waveform diagram of a clock signal provided by an embodiment of the present disclosure;

FIG. 9 is a schematic structural diagram of another shift register provided by an embodiment of the present disclosure;

FIG. 10 is a schematic structural diagram of another shift register provided by an embodiment of the present disclosure;

FIG. 11 is a schematic structural diagram of another shift register provided by an embodiment of the present disclosure;

FIG. 12 is a schematic driving timing waveform diagram of a shift register provided by an embodiment of the present disclosure;

FIG. 13 is a schematic driving timing waveform diagram of another shift register provided by an embodiment of the present disclosure;

FIG. 14 is a schematic driving timing waveform diagram of another shift register provided by an embodiment of the present disclosure;

FIG. 15 is a schematic structural diagram of another shift register provided by an embodiment of the present disclosure;

FIG. 16 is a schematic structural diagram of another shift register provided by an embodiment of the present disclosure;

FIG. 17 is a schematic structural diagram of another shift register provided by an embodiment of the present disclosure;

FIG. 18 is a schematic structural diagram of another shift register provided by an embodiment of the present disclosure;

FIG. 19 is a schematic structural diagram of another shift register provided by an embodiment of the present disclosure;

FIG. 20 is a schematic structural diagram of a gate drive circuit provided by an embodiment of the present disclosure;

FIG. 21 is a schematic driving timing waveform diagram of another shift register provided by an embodiment of the present disclosure;

FIG. 22 is a schematic structural diagram of a gate drive circuit provided by an embodiment of the present disclosure.

### DETAILED DESCRIPTION

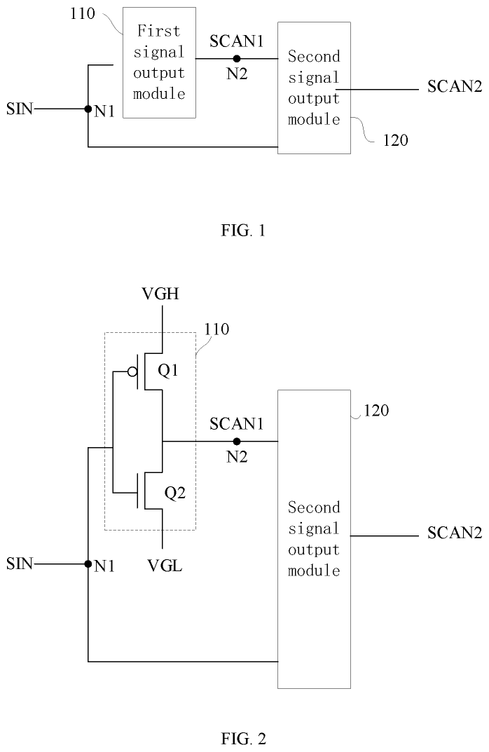

FIG. 1 is a schematic structural diagram of a shift register according to an embodiment of the present disclosure.

Referring to FIG. 1, the shift register provided in this embodiment includes: a first signal output module 110 and a second signal output module 120, and a control terminal of the first signal output module 110 and a first control terminal of the second signal output module 120 are connected at a first node N1, the first node N1 is configured to receive a start signal SIN, a second control terminal of the second signal output module 120 and an output terminal of the first signal output module 110 are connected at a second node N2, the first signal output module 110 is configured to output a first gate drive signal SCAN1 to the second node N2 based on a voltage at the first node N1, and the second signal output module 120 is configured to output a second gate drive signal SCAN2 based on the voltage at the first node N1 and a voltage at the second node N2.

A short pulse width level of the first gate drive signal SCAN1 is opposite to a short pulse width level of the second gate drive signal SCAN2. Here, the short pulse width level refers to an effective level of the gate drive signal capable of turning on a corresponding transistor. For example, if the first gate drive signal SCAN1 is used to drive an N-type transistor, then the short pulse width level of the first gate drive signal SCAN1 is a high level, and the long pulse width level of the first gate drive signal SCAN1 is a low level, i.e., an on-time of the transistor connected to the first gate drive signal SCAN1 is shorter than an off-time. For another example, if the second gate drive signal SCAN2 is used to drive a P-type transistor, then the short pulse width level of the second gate drive signal SCAN2 is a low level, and the long pulse width level of the second gate drive signal SCAN2 is a high level.

In one embodiment, when the start signal SIN is a first level pulse (e.g., a low level pulse), the voltage at the first node N1 is the voltage of the first level pulse of the start signal SIN, the first signal output module 110 responds to the voltage at the first node N1 to output the short pulse width level of the first gate drive signal SCAN1, while the second signal output module 120 responds to the voltage at the first node N1 and the voltage at the second node N2 to output the long pulse width level of the second gate drive signal SCAN2.

Subsequently, for a period of time, the start signal SIN no longer controls the voltage at the first node N1. The first node N1 continuously maintains the voltage of the first level pulse, and the voltage at the second node N2 is maintained at the short pulse width level of the first gate drive signal SCAN1.

Then, under the action of a corresponding clock signal (not shown in the figure), the second signal output module 120 responds to the voltage at the first node N1 and the voltage at the second node N2 to output the short pulse width level of the second gate drive signal SCAN2.

When the start signal SIN again controls the potential at the first node N1, the start signal SIN has transitioned from the first level pulse to a second level pulse (e.g., a high level pulse), the voltage at the first node N1 is the voltage of the second level pulse of the start signal SIN, the first signal output module 110 responds to the voltage at the first node N1 to output the long pulse width level of the first gate drive signal SCAN1, while the second signal output module 120 responds to the voltage at the first node N1 and the voltage at the second node N2 to output the long pulse width level of the second gate drive signal SCAN2, thereby forming the first gate drive signal SCAN1 and the second gate drive signal SCAN2, respectively.

The embodiments provided by the embodiment of the present disclosure, by controlling the voltage at the first node N1, enables the first signal output module 110 to output the first gate drive signal SCAN1 to the second node N2 based on the voltage at the first node N1, and controls the second signal output module 120 to output the second gate drive signal SCAN2 based on the voltage at the first node N1 and the voltage at the second node N2, and the first node N1 is configured to receive the start signal, and the second node N2 is configured to output the first gate drive signal SCAN1, and the short pulse width level of the first gate drive signal SCAN1 is opposite to the short pulse width level of the second gate drive signal SCAN2. Compared with solutions in the related art, the embodiments provided in this embodiment, through mutual borrowing and coordinated cooperation between the first signal output module 110 and the second signal output module 120, can output two different types of gate drive signals, and has a simple circuit structure, which is beneficial for compressing the bezel of a display panel and achieving a narrow bezel design.

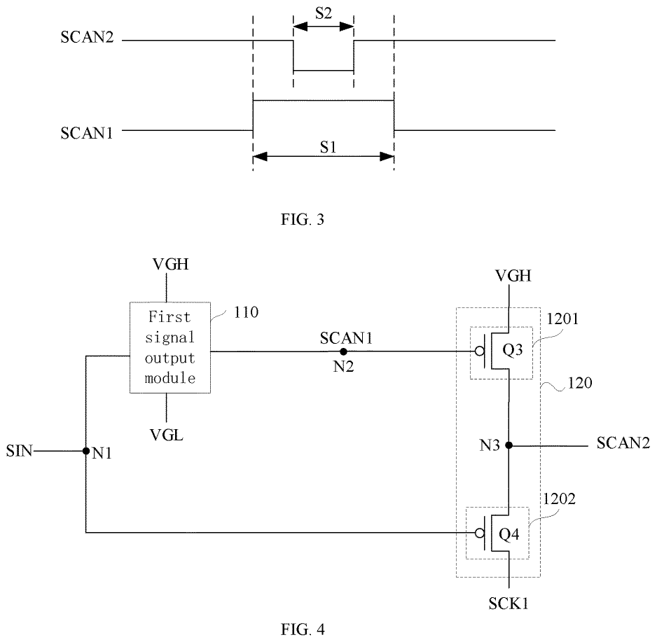

FIG. 2 is a schematic structural diagram of another shift register provided by an embodiment of the present disclosure, and FIG. 3 is a schematic waveform diagram of a gate drive signal provided by an embodiment of the present disclosure. Referring to FIG. 2 and FIG. 3, based on the above embodiment, the short pulse width level S1 of the first gate drive signal SCAN1 covers the short pulse width level S2 of the second gate drive signal SCAN2. In one embodiment, a first input terminal of the first signal output module 110 receives a first voltage signal VGH, a second input terminal of the first signal output module 110 receives a second voltage signal VGL, and the first signal output module 110 is configured to respond to the voltage at the first node N1 to output the first voltage signal VGH or the second voltage signal VGL to the second node N2, while outputting the first gate drive signal SCAN1.

In this embodiment, the first signal output module 110 includes a first transistor Q1 and a second transistor Q2. The control electrode of the first transistor Q1 and the control electrode of the second transistor Q2 are both connected to the first node N1. The first electrode of the first transistor Q1 receives a first voltage signal VGH, and the second electrode of the first transistor Q1 and the second electrode of the second transistor Q2 are both connected to the second node N2. The first electrode of the second transistor Q2 receives a second voltage signal VGL. The channel type of the first transistor Q1 is different from the channel type of the second transistor Q2. When a first level pulse of a start signal SIN is transmitted to the first node N1, the first transistor Q1 is turned on in response to the voltage at the first node N1, and the first transistor Q1 transmits the first voltage signal VGH to the second node N2. When the start signal SIN does not control the voltage at the first node N1, the first node N1 maintains the first level pulse, the first transistor Q1 remains turned on, and the second node N2 maintains the first voltage signal VGH.

During this process, the second signal output module 120 outputs a short pulse width level of a second gate driving signal SCAN2 in response to the voltage at the first node N1 and the voltage at the second node N2, thereby achieving that a short pulse width level S1 of a first gate driving signal SCAN1 covers a short pulse width level S2 of the second gate driving signal SCAN2. Since the short pulse width of the first gate driving signal SCAN1 is a high level, setting the short pulse width level S1 of the first gate driving signal SCAN1 to cover the short pulse width level S2 of the second gate driving signal SCAN2 is beneficial for improving the switching speed of an N-type transistor, and the on-resistance of the N-type transistor is relatively small, thereby reducing the power consumption of the N-type transistor within one cycle, and further reducing the overall power consumption of the display panel.

When a second level pulse of the start signal SIN is transmitted to the first node N1, the second transistor Q2 is turned on in response to the voltage at the first node N1, and the second transistor Q2 transmits the second voltage signal VGL to the second node N2, outputting a long pulse width level of the first gate driving signal SCAN1.

In one embodiment, the first transistor Q1 is a P-type transistor, and the second transistor Q2 is an N-type transistor.

In one embodiment, the level of the first voltage signal VGH is greater than the level of the second voltage signal VGL, the level of the first voltage signal VGH is the short pulse width level S1 of the first gate driving signal SCAN1, and the second voltage signal VGL is the long pulse width level of the first gate driving signal SCAN1.

FIG. 4 is a schematic structural diagram of another shift register provided in an embodiment of the present disclosure. Referring to FIG. 4, based on the above embodiments, a first input terminal of the second signal output module 120 receives the first voltage signal VGH, a second input terminal of the second signal output module 120 receives a first clock signal SCK1, and the second signal output module 120 is configured to output the first voltage signal VGH or the first clock signal SCK1 in response to the voltage at the first node N1 and the voltage at the second node N2, to output the second gate driving signal SCAN2.

In one embodiment, the second signal output module 120 includes a first output unit 1201 and a second output unit 1202. The first output unit 1201 includes a third transistor Q3, and the second output unit 1202 includes a fourth transistor Q4. The control electrode of the third transistor Q3 is connected to the second node N2, the first electrode of the third transistor Q3 receives the first voltage signal VGH, the second electrode of the third transistor Q3 and the second electrode of the fourth transistor Q4 are connected to a third node N3, the third node N3 is connected to the output terminal of the second signal output module 120, and the first electrode of the fourth transistor Q4 receives the first clock signal SCK1.

When the first level pulse of the start signal SIN is transmitted to the first node N1, the fourth transistor Q4 is turned on in response to the voltage at the first node N1, outputting the first clock signal SCK1 to the third node N3, and the third transistor Q3 is turned off in response to the voltage at the second node N2. When the second level pulse of the start signal SIN is transmitted to the first node N1, the fourth transistor Q4 is turned off in response to the voltage at the first node N1, and the third transistor Q3 is turned on in response to the voltage at the second node N2, outputting the first voltage signal VGH to the third node N3.

In one embodiment, the second signal output module 120 formed by the first output unit 1201 and the second output unit 1202, under the combined action of the voltages at the first node N1 and the second node N2, can output the second gate driving signal SCAN2 of a type different from the first gate driving signal SCAN1. The circuit structure is simple, which is beneficial for compressing the bezel of the display panel and achieving a narrow bezel design.

FIG. 5 is a schematic structural diagram of another shift register provided in an embodiment of the present disclosure. Referring to FIG. 5, based on the above embodiment, in one embodiment, the second signal output module 120 further includes a coupling unit 1203. The coupling unit 1203 is connected between the third node N3 and a second control terminal of the second signal output module 120, and the coupling unit 1203 is configured to couple the potential of the second control terminal of the second signal output module 1202.

In one embodiment, during the process in which the third node N3 outputs the first clock signal SCK1, when the first clock signal SCK1 transitions from a high level to a low level, under the coupling effect of the coupling unit 1203, the potential of the second control terminal of the second signal output module 1202 is pulled low, improving the turn-on performance of the fourth transistor Q4, ensuring that the fourth transistor Q4 is strongly turned on, ensuring signal output at the third node N3, and facilitating improvement of the output stability of the second gate driving signal SCAN2. The coupling unit 1203 includes a first capacitor C1. A first terminal of the first capacitor C1 is connected to the third node N3, and a second terminal of the first capacitor C1 is connected to the second control terminal of the second signal output module 120.

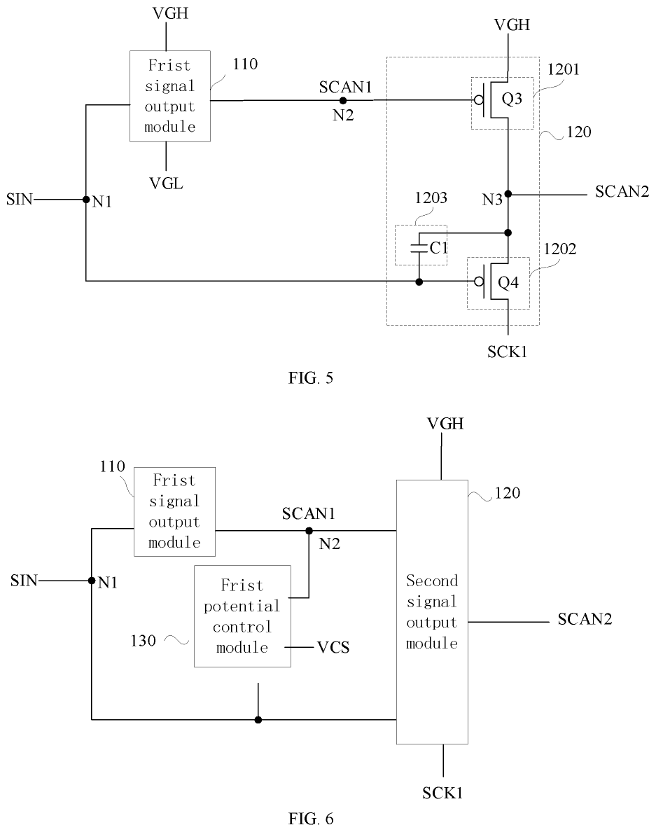

FIG. 6 is a structural schematic diagram of another shift register provided in an embodiment of the present disclosure. Referring to FIG. 6, on the basis of the above embodiments, the shift register further includes a first potential control module 130, a first control terminal of the first potential control module 130 is connected to a second node N2, a second control terminal of the first potential control module 130 receives a voltage control signal VCS, an input terminal of the first potential control module 130 receives a first voltage signal VGH, an output terminal of the first potential control module 130 is connected to a first node N1, and the first potential control module 130 is configured to control a voltage of the first node N1 based on a voltage of the second node N2 and the voltage control signal VCS.

In combination with FIG. 5 and FIG. 6, when the voltage of the second node N2 causes a third transistor Q3 to be turned on, a second signal output module 120 outputs a long pulse width level of a second gate driving signal SCAN2. During a process in which a start signal SIN releases control of the potential of the first node N1, the first potential control module 130 responds to the voltage of the second node N2 and the voltage control signal VCS to be turned on, transmitting the first voltage signal VGH to the first node N1 to maintain the voltage of the first node N1, thereby ensuring stability of the voltage of the second node N2, and further improving output stability of a first gate driving signal SCAN1 and the second gate driving signal SCAN2.

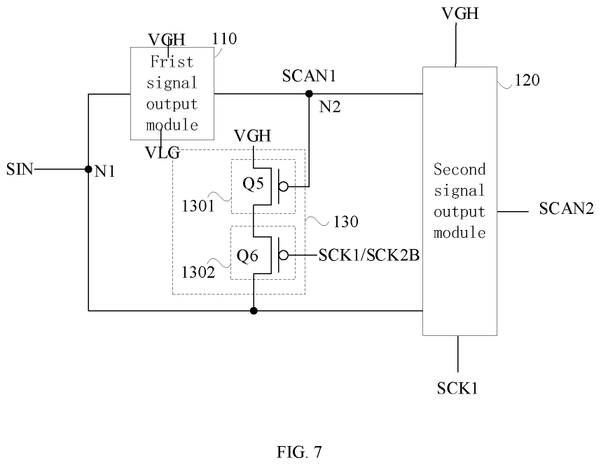

FIG. 7 is a structural schematic diagram of another shift register provided in an embodiment of the present disclosure. Referring to FIG. 6 and FIG. 7, on the basis of the above embodiments, the first potential control module 130 includes a first subunit 1301 and a second subunit 1302, a control terminal of the first subunit 1301 is connected to the second node N2, a first terminal of the first subunit 1301 receives the first voltage signal VGH, a second terminal of the first subunit 1301 is connected to a first terminal of the second subunit 1302, a second terminal of the second subunit 1302 is connected to the first node N1, and a control terminal of the second subunit 1302 receives the voltage control signal VCS.

In one embodiment, when the start signal SIN releases voltage control of the first node N1, during a process in which a first signal output module 110 outputs a second voltage signal VGL to the second node N2, the first subunit 1301 responds to the voltage of the second node N2 to be turned on, the second subunit 1302 responds to the voltage control signal VCS to be turned on, and the first voltage signal VGH is transmitted to the first node N1 via the first subunit 1301 and the second subunit 1302, maintaining the first node N1 at a high level, thereby enabling the first signal output module 110 to continuously output the second voltage signal VGL, ensuring stability of the voltage of the second node N2.

In this embodiment, the first subunit 1301 includes a fifth transistor Q5, the second subunit 1302 includes a sixth transistor Q6, a control electrode of the fifth transistor Q5 is connected to the second node N2, a first electrode of the fifth transistor Q5 receives the first voltage signal VGH, a second electrode of the fifth transistor Q5 is connected to a first electrode of the sixth transistor Q6, a second electrode of the sixth transistor Q6 is connected to the first node N1, and a control electrode of the sixth transistor Q6 receives the voltage control signal VCS. Here, a channel type of the fifth transistor Q5 is the same as a channel type of the sixth transistor Q6, for example, both the fifth transistor Q5 and the sixth transistor Q6 are P-type transistors.

In one embodiment, the voltage control signal VCS may include a first clock signal SCK1 or a second clock signal SCK2B.

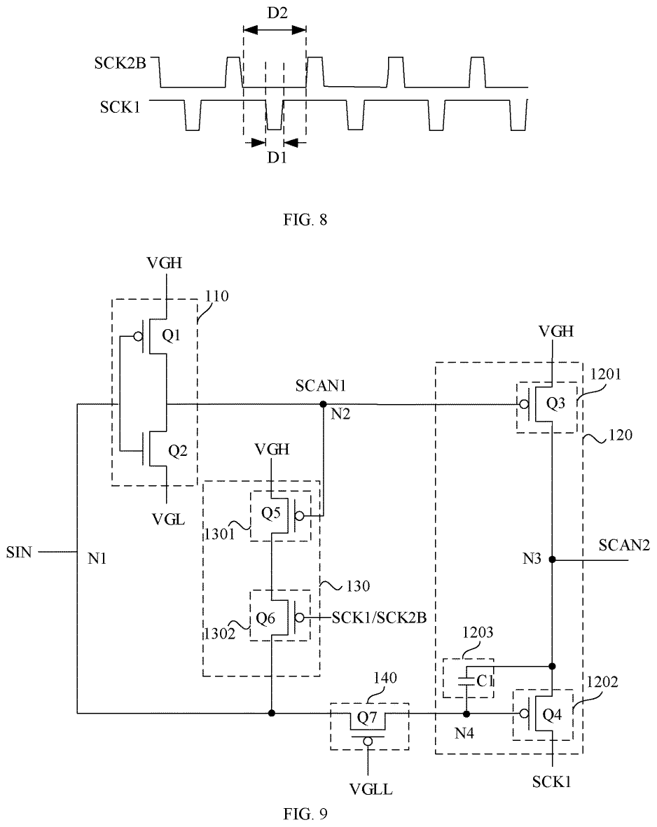

FIG. 8 is a waveform schematic diagram of a clock signal provided in an embodiment of the present disclosure. Referring to FIG. 8, a low-level duration D2 of the second clock signal SCK2B is greater than a low-level duration D1 of the first clock signal SCK1. When the second clock signal SCK2B is used to control the control electrode of the sixth transistor Q6, a turn-on duration of the sixth transistor Q6 can be extended, thereby reducing a duration during which the first node N1 is in a floating state during the process in which the start signal SIN releases control of the voltage of the first node N1, which is beneficial for making the potential of the first node N1 more stable and improving the anti-interference capability of the shift register.

FIG. 9 is a structural schematic diagram of another shift register provided in an embodiment of the present disclosure. Referring to FIG. 9, on the basis of the above embodiments, an auxiliary module 140 is further included on a connection path between the first node N1 and a first control terminal of the second signal output module 120, a first terminal of the auxiliary module 140 is connected to the first node N1, a second terminal of the auxiliary module 140 is connected to the first control terminal of the second signal output module 120, a control terminal of the auxiliary module 140 receives a third voltage signal VGLL, and the auxiliary module 140 is configured to prevent a voltage of the first control terminal of the second signal output module 120 from being transmitted to the first node N1.

In one embodiment, during a process in which a fourth transistor Q4 transmits the first clock signal SCK1 to a third node N3, when the voltage of the third node N3 transitions from a high level of the first clock signal SCK1 to a low level, under a coupling effect of a first capacitor C1, a voltage of a fourth node N4 is pulled to a lower level. By providing the auxiliary module 140, an extremely low level of the fourth node N4 can be isolated, preventing the extremely low level of the fourth node N4 from being transmitted to the first node N1, thereby ensuring that the voltage of the first node N1 is not excessively low (when the voltage of the first node N1 drops to a value, a seventh transistor Q7 will be turned off), which is beneficial for reducing bias voltages of transistors connected to the first node N1 and improving stability of the transistors connected to the first node N1.

In one embodiment, the auxiliary module 140 includes a seventh transistor Q7, a control electrode of the seventh transistor Q7 receives the third voltage signal VGLL, a first electrode of the seventh transistor Q7 is connected to the first node N1, and a second electrode of the seventh transistor Q7 is connected to the first control terminal of the second signal output module 120.

In this embodiment, the level of the third voltage signal VGLL is lower than the level of the second voltage signal VGL. The advantage of this configuration is that when the first node N1 is at the low level of the start signal SIN (e.g., VGL), since the third voltage signal VGLL is lower than the second voltage signal VGL, the seventh transistor Q7 is turned on more fully, allowing the voltage of the fourth node N4 to reach the level of VGL, reducing threshold voltage loss during low-level transmission. This enables the fourth transistor T4 to achieve a lower level under the coupling effect of the first capacitor C1, providing a stronger driving force for the fourth transistor T4 with the same size, thereby reducing the rise and fall times of the second gate drive signal SCAN2, which is beneficial for improving the driving capability and stability of the second gate drive signal SCAN2. Furthermore, when the fourth node N4 is reduced to an extremely low level, the seventh transistor Q7 can lower the voltage of the first node N1 (without reducing it to the voltage of the fourth node N4). By maintaining the voltage of the first node N1 at a lower level, it is advantageous for eliminating leakage current caused by incomplete turn-off of the second transistor T2, thereby reducing unnecessary power consumption.

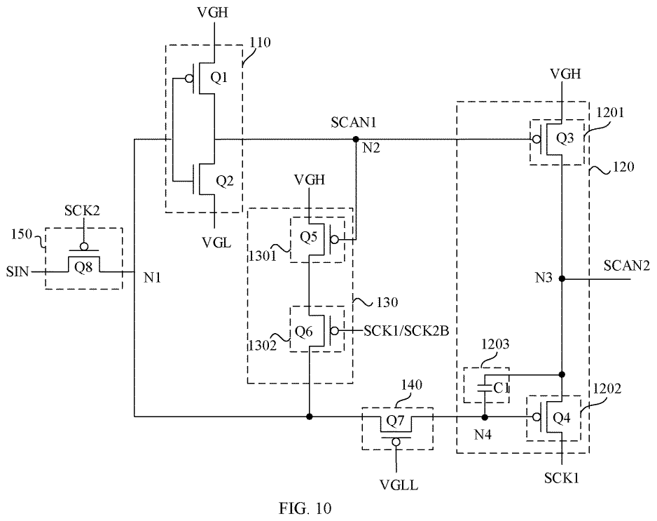

FIG. 10 is a schematic structural diagram of another shift register provided by an embodiment of the present disclosure. Referring to FIG. 10, based on the above embodiments, the shift register further includes an input module 150. A first control terminal of the input module 150 is connected to a third clock signal SCK2, an input terminal of the input module 150 is connected to the start signal SIN, an output terminal of the input module 150 is connected to the first node N1, and the input module 150 is used to transmit the start signal SIN. By providing the input module 150, the timing at which the start signal SIN is transmitted to the first node N1 can be flexibly controlled.

The third clock signal SCK2 and the second clock signal SCK2B are inverse signals to each other. When the input module 150 is turned on in response to the third clock signal SCK2, the start signal SIN can be transmitted to the first node N1 via the input module 150; when the input module 150 is turned off in response to the third clock signal SCK2, the start signal SIN ceases to control the voltage of the first node N1.

Continuing to refer to FIG. 10, the input module 150 includes an eighth transistor Q8. A control electrode of the eighth transistor Q8 is connected to the third clock signal SCK2, a first electrode of the eighth transistor Q8 is connected to the start signal SIN, and a second electrode of the eighth transistor Q8 is connected to the first node N1.

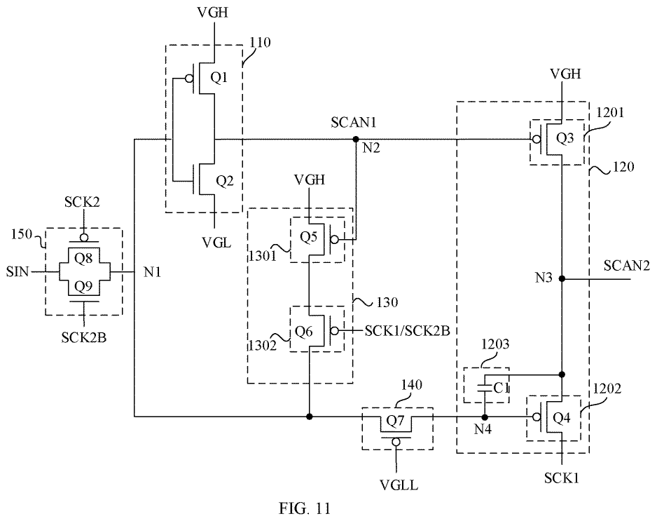

FIG. 11 is a schematic structural diagram of another shift register provided by an embodiment of the present disclosure. Referring to FIG. 11, based on the above embodiment, the input module 150 further includes a second control terminal, and the second control terminal of the input module 150 is connected to the second clock signal SCK2B. The input module 150 further includes a ninth transistor Q9. A control electrode of the ninth transistor Q9 is connected to the second clock signal SCK2B, a first electrode of the ninth transistor Q9 is connected to the first electrode of the eighth transistor Q8, and a second electrode of the ninth transistor Q9 is connected to the first node N1.

In this embodiment, the channel type of the eighth transistor Q8 is different from that of the ninth transistor Q9. For example, the eighth transistor Q8 is a P-type transistor, and the ninth transistor Q9 is an N-type transistor. By providing the eighth transistor Q8 and the ninth transistor Q9 with different channel types, the level loss when transmitting the start signal SIN is reduced, improving the transmission quality of the start signal SIN, which is beneficial for enhancing the reliability of the voltage at the first node N1.

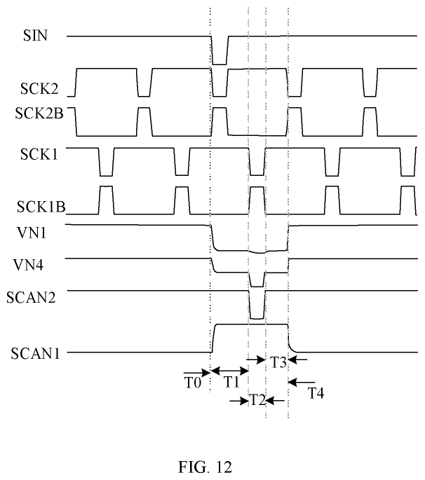

In one embodiment, the eighth transistor Q8 and the ninth transistor Q9 are turned on simultaneously under the control of the second clock signal SCK2B and the third clock signal SCK2, which are inverse signals to each other. FIG. 12 is a schematic diagram of a driving timing waveform of a shift register provided by an embodiment of the present disclosure, which is applicable to the shift register provided by any of the above embodiments. Referring to FIG. 12, the first clock signal SCK1, the second clock signal SCK2B, and the third clock signal SCK2 each include alternating first-level pulses and second-level pulses. The voltage value of the first-level pulse is less than the voltage value of the second-level pulse. For example, the first-level pulse can be a low-level pulse, and the second-level pulse can be a high-level pulse. The setting of high and low level pulses ensures the normal operation of the shift register.

In one embodiment, the single pulse width of the first-level pulse of the first clock signal SCK1 is the same as the single pulse width of the first-level pulse of the third clock signal SCK2, the single pulse width of the second-level pulse of the first clock signal SCK1 is the same as the single pulse width of the second-level pulse of the third clock signal SCK2, and the single pulse width of the second-level pulse of the first clock signal SCK1 is greater than the single pulse width of the first-level pulse of the first clock signal SCK1. That is, the waveform of the first clock signal SCK1 has a different phase from the waveform of the third clock signal SCK2.

The periods of the first clock signal SCK1 and the third clock signal SCK2 are both T, and the start time of the first first-level pulse of the first clock signal SCK1 differs from the start time of the first first-level pulse of the third clock signal SCK2 by T/2. The time of the second-level pulse of the third clock signal SCK2 covers the time of the first-level pulse of the first clock signal line SCK1, and the time of the second-level pulse of the first clock signal SCK1 covers the time of the first-level pulse of the third clock signal SCK2. Here, by controlling the phases of the first clock signal SCK1, the second clock signal SCK2B, and the third clock signal SCK2, precise output of the first gate drive signal SCAN1 and the second gate drive signal SCAN2 can be achieved during the operation of the shift register, ensuring that the shift register can operate normally.

In one embodiment, the second gate driving signal SCAN2 includes at least one first level pulse, and the duration of a single first level pulse of the start signal SIN is greater than or equal to the duration of a single first level pulse of the third clock signal SCK2. For example, when the duration of a single first level pulse of the start signal SIN is equal to the duration of a single first level pulse of the third clock signal SCK2, i.e., within the duration of the first level pulse of the start signal SIN, only one first level pulse of the third clock signal SCK2 is included, and at this time, the second gate driving signal SCAN2 outputs one first level pulse.

When the duration of a single first level pulse of the start signal SIN is greater than the duration of a single first level pulse of the third clock signal SCK2, i.e., within the duration of the first level pulse of the start signal SIN, multiple first level pulses of the third clock signal SCK2 are included, and at this time, the second gate driving signal SCAN2 outputs multiple first level pulses. The number of first level pulses of the third clock signal SCK2 within the duration of the first level pulse of the start signal SIN is the same as the number of first level pulses of the second gate driving signal SCAN2.

In this embodiment, by configuring the start signal SIN and the third clock signal SCK2, multi-level pulse or single-level pulse output of the second gate driving signal SCAN2 can be achieved to meet different application requirements, which is beneficial for improving the compatibility of the gate driving circuit.

In one embodiment, the single pulse width of the first level pulse of the second gate driving signal SCAN2 is the same as the single pulse width of the first level pulse of the start signal SIN, and the first level pulse of the second gate driving signal SCAN2 is a short pulse width level.

In one embodiment, the first gate driving signal SCAN1 includes at least one second level pulse, and the pulse width of the second level pulse of the first gate driving signal SCAN1 is equal to one period T of the third clock signal SCK2. The start signal includes at least one first level pulse, and between two adjacent first level pulses of the start signal SIN, at least one first level pulse of the third clock signal SCK2 is interposed to form multiple second level pulses of the first gate driving signal SCAN1.

The second level pulse of the first gate driving signal SCAN1 is a short pulse width level. In this embodiment, by configuring the start signal SIN and the third clock signal SCK2, multi-level pulse or single-level pulse output of the first gate driving signal SCAN1 can be achieved to meet different application requirements, which is beneficial for improving the compatibility of the gate driving circuit.

In one embodiment, this embodiment further includes a fourth clock signal SCK1B, which is used to replace the second clock signal SCK2B in the next-stage shift register to control the on/off of the input module 150. When proceeding to the next-next-stage shift register, it reverts to the fourth clock signal SCK1B, thereby achieving the shift output of the gate driving signal.

Referring to FIGS. 11 and 12, the operation process of the shift register provided in this embodiment is as follows:

In the T0 phase, the start signal SIN is a high-level pulse (second level pulse), the voltages of the first node N1 and the fourth node N4 remain high under the action of the first capacitor C1, the second node N2 outputs a long pulse width level (low level) of the first gate driving signal SCAN1, and the third node N3 outputs a long pulse width level (high level) of the second gate driving signal SCAN2.

In the T1 phase, the start signal SIN is a low-level pulse (first level pulse), the first clock signal SCK1 is a high-level pulse (second level pulse), the second clock signal SCK2B is a high-level pulse (second level pulse), and the third clock signal SCK2 is a low-level pulse (first level pulse). Therefore, the eighth transistor Q8 and the ninth transistor Q9 are turned on, transmitting the start signal SIN to the first node N1, and the potential of the first node N1 is low. The first transistor Q1 is turned on in response to the voltage of the first node N1 and outputs a first voltage signal VGH to the second node N2, i.e., outputting a short pulse width level of the first gate driving signal SCAN1.

Under the action of the voltage of the first node N1 and the third voltage signal VGLL, the seventh transistor Q7 is turned on, and the voltage of the fourth node N4 can reach the same low level as the first node N1, causing the fourth transistor Q4 to be turned on. The fourth transistor Q4 transmits the high level of the first clock signal SCK1 to the third node N3, i.e., outputting a long pulse width level of the second gate driving signal SCAN2.

In the T2 phase, the start signal SIN is a high-level pulse (second level pulse), the first clock signal SCK1 is a low-level pulse (first level pulse), the second clock signal SCK2B is a low-level pulse (first level pulse), and the third clock signal SCK2 is a high-level pulse (second level pulse). The eighth transistor Q8 and the ninth transistor Q9 are turned off, and the start signal SIN releases control over the voltage of the first node N1. Since the first clock signal SCK1 transitions from high to low, and the third node N3 outputs the first clock signal SCK1, i.e., outputting a short pulse width level of the second gate driving signal SCAN2, under the coupling effect of the first capacitor C1, the voltage of the fourth node N4 is pulled to a lower voltage level to ensure strong conduction of the fourth transistor Q4. At this time, under the action of the seventh transistor Q7, the voltage of the first node N1 does not decrease significantly; otherwise, the seventh transistor Q7 would be turned off. Since the voltage of the first node N1 remains low, the voltage of the second node N2 remains unchanged.

In the T3 phase, the first clock signal SCK1 transitions from low to high, and the third node N3 outputs a long pulse width level of the second gate driving signal SCAN2. The eighth transistor Q8 and the ninth transistor Q9 remain off, and the voltages of the first node N1 and the second node N2 remain unchanged.

In the T4 phase, the start signal SIN is a high-level pulse (second-level pulse), the first clock signal SCK1 is a high-level pulse (second-level pulse), the second clock signal SCK2B is a high-level pulse (second-level pulse), and the third clock signal SCK2 is a low-level pulse (first-level pulse). The eighth transistor Q8 and the ninth transistor Q9 are turned on, transmitting the start signal SIN to the first node N1, where the voltage of the first node N1 is at a high level. The second transistor Q2 is turned on in response to the voltage of the first node N1, and transmits the second voltage signal VGL to the second node N2, i.e., the second node N2 outputs a long pulse width level of the first gate drive signal SCAN1. The third transistor Q3 is turned on in response to the voltage of the second node N2, and the first voltage signal VGH is transmitted through the third transistor Q3 to the third node N3, i.e., the third node N3 outputs a long pulse width level of the second gate drive signal SCAN2.

Under the action of the voltage of the second node N2 and the first clock signal SCK1 (or the second clock signal SCK2B), the fifth transistor Q5 and the sixth transistor Q6 are turned on, transmitting the first voltage signal VGH to the first node N1 to maintain the high level of the first node N1, thereby stabilizing the voltage of the second node N2.

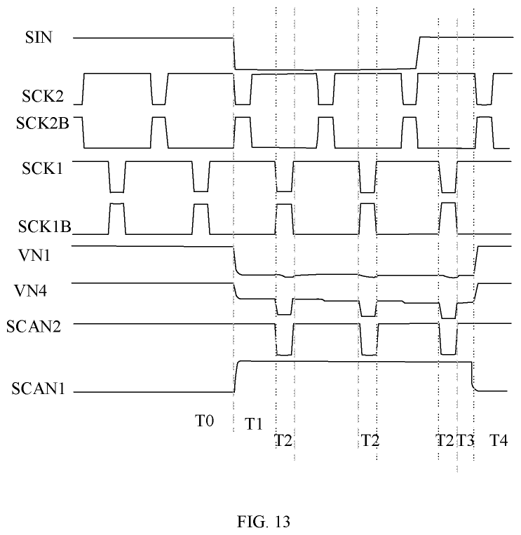

FIG. 13 is a schematic diagram of a drive timing waveform of another shift register provided in an embodiment of the present disclosure, which is also applicable to the shift register shown in FIG. 11. Different from the timing shown in FIG. 12, in the timing shown in FIG. 13, when the duration of a single first-level pulse of the start signal SIN is greater than the duration of a single first-level pulse of the third clock signal SCK2, within the duration of the first-level pulse of the start signal SIN, multiple first-level pulses of the third clock signal SCK2 are included, and the second gate drive signal SCAN2 outputs multiple first-level pulses. In this embodiment, the number of first-level pulses of the third clock signal SCK2 within the duration of the first-level pulse of the start signal SIN is the same as the number of first-level pulses of the second gate drive signal SCAN2.

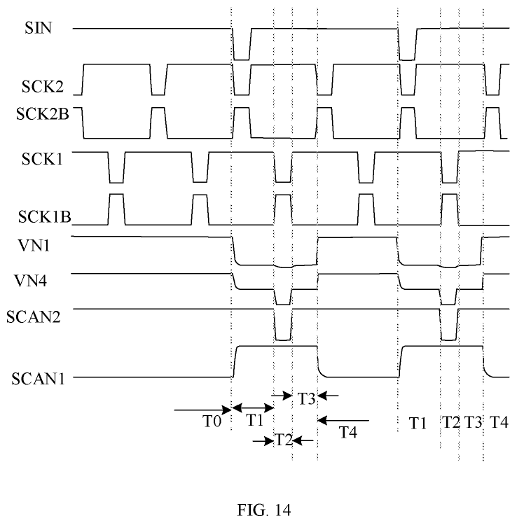

FIG. 14 is a schematic diagram of a drive timing waveform of another shift register provided in an embodiment of the present disclosure, which is also applicable to the shift register shown in FIG. 11. Different from the timing shown in FIG. 12, in the timing shown in FIG. 14, the first gate drive signal SCAN1 includes multiple second-level pulses, and the pulse width of the second-level pulses of the first gate drive signal SCAN1 is equal to one period T of the third clock signal SCK2. In one embodiment, the start signal includes multiple first-level pulses (such as two first-level pulses in FIG. 14), and between two adjacent first-level pulses of the start signal SIN, at least one first-level pulse of the third clock signal SCK2 is arranged at an interval, to form multiple second-level pulses of the first gate drive signal SCAN1. The working process of the shift register corresponding to the drive timings shown in FIGS. 13 and 14 will not be described in detail here.

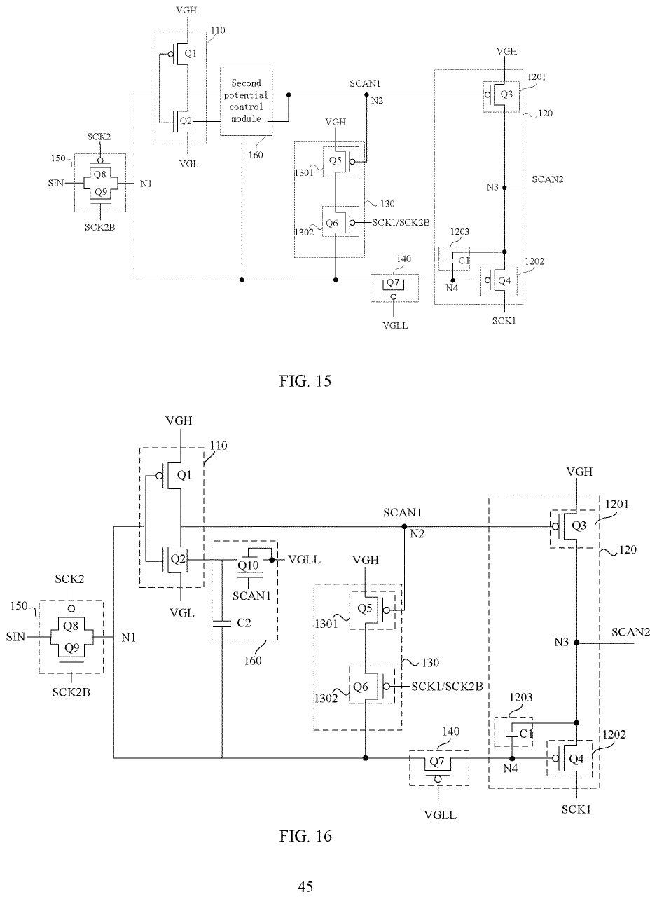

FIG. 15 is a schematic structural diagram of another shift register provided in an embodiment of the present disclosure.

Referring to FIG. 15, based on the above embodiments, the second transistor Q2 is a vertical dual-gate transistor, and the second transistor Q2 includes a first gate and a second gate. The first gate of the second transistor Q2 and the control electrode of the first transistor Q1 are both connected to the first node N1.

The shift register further includes a second potential control module 160, which is connected between the first node N1 and the second gate of the second transistor Q2. The control terminal of the second potential control module 160 is connected to the second node N2. The second potential control module 160 is used to control the voltage of the second gate of the second transistor Q2 according to the voltage of the first node N1 and the voltage of the second node N2, which is beneficial to reducing the leakage current of the second transistor Q2.

In one embodiment, FIG. 16 is a schematic structural diagram of another shift register provided in an embodiment of the present disclosure.

Referring to FIG. 16, the second potential control module 160 includes a second capacitor C2 and a tenth transistor Q10. The first gate of the tenth transistor Q10 is connected to the second node N2, the first electrode of the tenth transistor Q10 is connected to a third voltage signal VGLL, the second electrode of the tenth transistor Q10 is connected to the second gate of the second transistor Q2, the first terminal of the second capacitor C2 is connected to the second gate of the second transistor Q2, and the second terminal of the second capacitor C2 is connected to the first node N1.

In one embodiment, when the voltage of the first node N1 jumps from a high level to a low level, the voltage of the second node N2 is at a high level, causing the tenth transistor Q10 to be turned on, transmitting the third voltage signal VGLL to the second gate of the second transistor Q2, and the voltage of the second gate of the second transistor Q2 is VGLL, thereby making the threshold state of the second transistor Q2 controllable. By adjusting the threshold voltage of the second transistor Q2, the leakage current of the second transistor Q2 can be reduced.

When the voltage of the first node N1 jumps from a low level to a high level, the tenth transistor Q10 is turned off. Under the coupling effect of the second capacitor C2, the voltage of the second gate of the second transistor Q2 increases, adjusting the threshold voltage of the second transistor to be negatively biased, enhancing the conduction capability of the second transistor. In another optional implementation manner provided by the present disclosure,

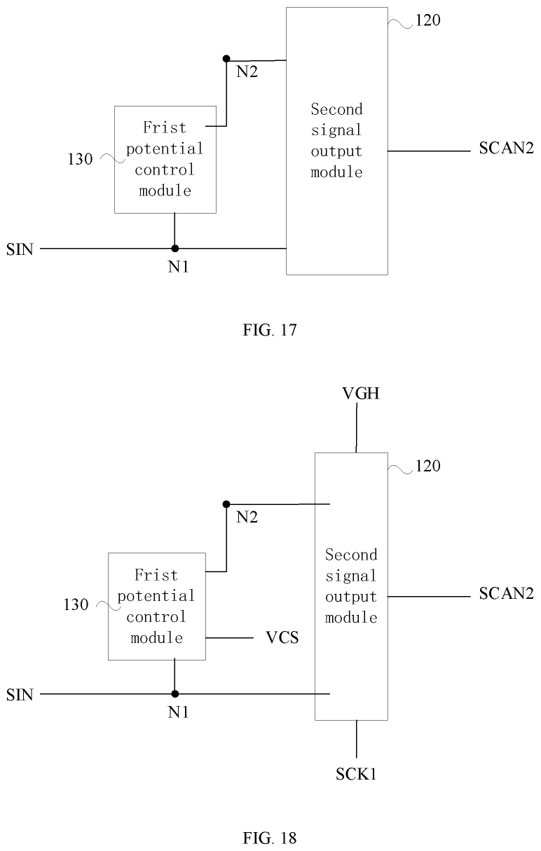

FIG. 17 is a schematic structural diagram of another shift register provided in an embodiment of the present disclosure.

Referring to FIG. 17, the shift register includes a second signal output module 120 and a first potential control module 130. The first control terminal of the second signal output module 120 and the output terminal of the first potential control module 130 are connected to the first node N1. The first node N1 is used to receive the start signal SIN. The second control terminal of the second signal output module 120 and the first control terminal of the first potential control module 130 are connected to the second node N2. The first potential control module 130 is used to control the voltage of the first node N1 according to the voltage of the second node N2. The second signal output module 120 is used to output the second gate drive signal SCAN2 according to the voltage of the first node N1 and the voltage of the second node N2.

In one embodiment, when the voltage at the second node N2 causes the second signal output module 120 to be turned on, the second signal output module 120 outputs a long pulse width level of the second gate driving signal SCAN2. During the process where the start signal SIN releases the voltage control of the first node N1, the first potential control module 130 responds to the voltage at the second node N2 and the voltage control signal VCS to be turned on, transmitting the first voltage signal VGH to the first node N1 to maintain the voltage at the first node N1, thereby ensuring the stability of the voltage at the second node N2 and consequently the stability of the second gate driving signal SCAN2.

In other embodiments, the ninth transistor Q9 may also be configured as a vertical dual-gate transistor to reduce the off-state leakage current of the ninth transistor Q9.

In one embodiment, the first gate of the N-type transistor is a top gate, and the second gate of the N-type transistor is a bottom gate; or, the first gate of the N-type transistor is a bottom gate, and the second gate of the N-type transistor is a top gate, which can be set according to actual requirements.

FIG. 18 is a schematic structural diagram of another shift register provided by an embodiment of the present disclosure.

Referring to FIG. 18, based on the above embodiments, the first potential control module 130 further includes a second control terminal, and the second control terminal of the first potential control module 130 is connected to the voltage control signal VCS; a first input terminal of the second signal output module 120 is connected to the first voltage signal VGH, a second input terminal of the second signal output module 120 is connected to the first clock signal SCK1, and the second signal output module 120 is configured to output the first voltage signal VGH or the first clock signal SCK1 in response to the voltage at the first node N1 and the voltage at the second node N2, to output the second gate driving signal SCAN2.

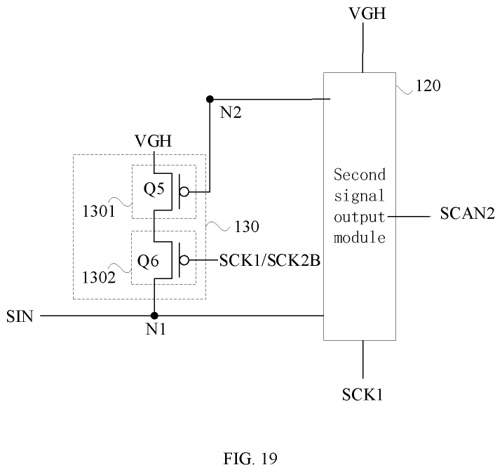

FIG. 19 is a schematic structural diagram of another shift register provided by an embodiment of the present disclosure.

Referring to FIG. 19, in one embodiment, the voltage control signal VCS includes the first clock signal SCK1 or the second clock signal SCK2B; both the first clock signal SCK1 and the second clock signal SCK2B include alternately arranged first level pulses and second level pulses, the time of the first level pulse of the second clock signal SCK2B covers the time of the first level pulse of the first clock signal SCK1, and the time of the second level pulse of the first clock signal SCK1 covers the time of the second level pulse of the second clock signal SCK2B. In one embodiment, the voltage value of the first level pulse is less than the voltage value of the second level pulse.

In one embodiment, the first potential control module 130 includes a first sub-unit 1301 and a second sub-unit 1302, a control terminal of the first sub-unit 1301 is connected to the second node N2, a first terminal of the first sub-unit 1301 is connected to the first voltage signal VGH, a second terminal of the first sub-unit 1301 is connected to a first terminal of the second sub-unit 1302, a second terminal of the second sub-unit 1302 is connected to the first node N1, and a control terminal of the second sub-unit 1302 is connected to the voltage control signal VCS.

In one embodiment, when the start signal SIN releases the voltage control of the first node N1, the first sub-unit 1301 is turned on in response to the voltage at the second node N2, the second sub-unit 1302 is turned on in response to the voltage control signal VCS, and the first voltage signal VGH is transmitted to the first node N1 through the first sub-unit 1301 and the second sub-unit 1302, maintaining the first node N1 at a high level, thereby causing the first signal output module 110 to continuously output the second voltage signal VGL, ensuring the stability of the voltage at the second node N2.

In this embodiment, the first sub-unit 1301 includes a fifth transistor Q5, the second sub-unit 1302 includes a sixth transistor Q6, a control electrode of the fifth transistor Q5 is connected to the second node N2, a first electrode of the fifth transistor Q5 is connected to the first voltage signal VGH, a second electrode of the fifth transistor Q5 is connected to a first electrode of the sixth transistor Q6, a second electrode of the sixth transistor Q6 is connected to the first node N1, and a control electrode of the sixth transistor Q6 is connected to the voltage control signal VCS. Here, the channel type of the fifth transistor Q5 is the same as the channel type of the sixth transistor Q6. For example, both the fifth transistor Q5 and the sixth transistor Q6 are P-type transistors.

In this embodiment, the low-level duration of the second clock signal SCK2B is greater than the low-level duration of the first clock signal SCK1. When the second clock signal SCK2B is used to control the control electrode of the sixth transistor Q6, the turn-on duration of the sixth transistor Q6 can be extended, thereby reducing the duration during which the first node N1 is in a floating state during the process where the start signal SIN releases the voltage control of the first node N1, which is beneficial for making the potential of the first node N1 more stable and improving the anti-interference capability of the shift register.

In one embodiment, referring to FIG. 15, the shift register further includes a first signal output module 110, an input module 150, an auxiliary module 140, and a second potential control module 160, and the specific working principles and structures thereof can be referred to the relevant descriptions in the above embodiments, which will not be repeated here.

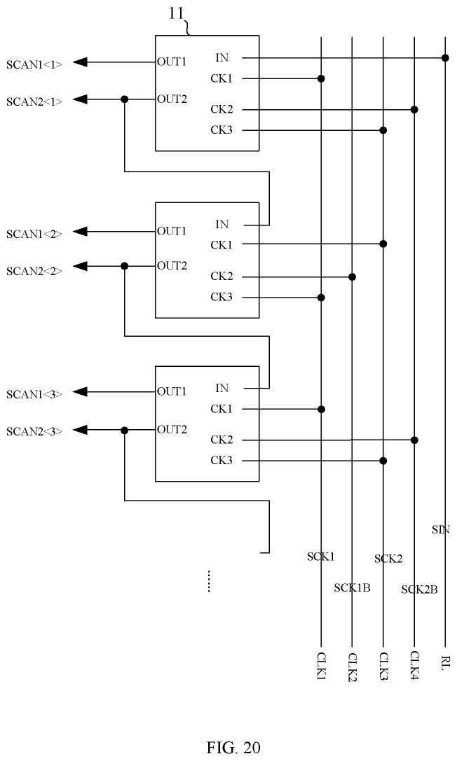

In one embodiment, an embodiment of the present disclosure further provides a display panel, which includes a gate driving circuit, and the gate driving circuit includes the shift register provided by any embodiment of the present disclosure, having the beneficial effects described in any of the above embodiments. FIG. 20 is a schematic structural diagram of a gate driving circuit provided by an embodiment of the present disclosure.

Referring to FIG. 15 and FIG. 20, a plurality of shift registers 11 are connected in cascade. In the plurality of cascaded shift registers 11, the start signal SIN input to a next-stage shift register 11 is provided by the output terminal of the second signal output module 120 of the current-stage shift register 11, and the start signal SIN of the first-stage shift register 11 is provided by the trigger signal line RL.

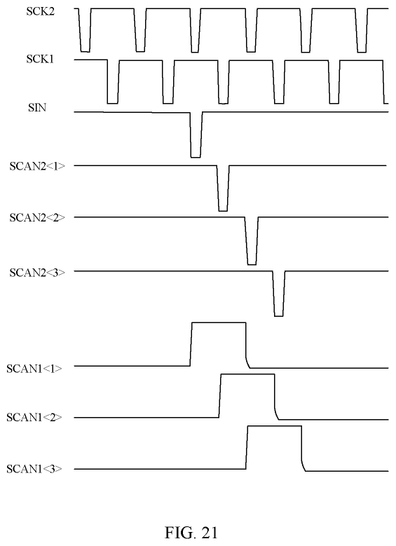

FIG. 21 is a schematic diagram of driving timing waveforms of another shift register provided in an embodiment of the present disclosure. The first gate driving signal SCAN1<1> output by the first-stage shift register 11, the first gate driving signal SCAN1<2> output by the second-stage shift register 11, and the first gate driving signal SCAN1<3> output by the third-stage shift register 11 are shifted stage by stage. The second gate driving signal SCAN2<1> output by the first-stage shift register 11, the second gate driving signal SCAN2<2> output by the second-stage shift register 11, and the second gate driving signal SCAN2<3> output by the third-stage shift register 11 are shifted stage by stage.

With reference to FIG. 20 and FIG. 21, the shift register 11 includes an input terminal IN, a first clock signal terminal CK1, a second clock signal terminal CK2, a third clock signal terminal CK3, a first output terminal OUT1, and a second output terminal OUT2. The input terminal IN of the next-stage shift register 11 is connected to the second output terminal OUT2 of the current-stage shift register 11. The shift register 11 further includes a first potential control module 130 and an input module 150. The input terminal of the input module 150 serves as the input terminal IN of the shift register 11. The output terminal of the first signal output module 110 serves as the first output terminal OUT1 of the shift register 11. The output terminal of the second signal output module 120 serves as the second output terminal OUT2 of the shift register 11. The second input terminal of the second signal output module 120 serves as the first clock signal terminal CK1 of the shift register 11. The second control terminal of the input module 150 serves as the second clock signal terminal CK2 of the shift register 11. The first control terminal of the input module 150 serves as the third clock signal terminal CK3 of the shift register 11.

The display panel further includes a first signal line CLK1, a second signal line CLK2, a third signal line CLK3, and a fourth signal line CLK4. The third clock signal terminal CK3 of the odd-stage shift register 11 is connected to the third signal line CLK3, and the third clock signal terminal CK3 of the even-stage shift register 11 is connected to the first signal line CLK1. The second clock signal terminal CK2 of the odd-stage shift register 11 is connected to the fourth signal line CLK4, and the second clock signal terminal CK2 of the even-stage shift register 11 is connected to the second signal line CLK2. The first clock signal terminal CK1 of the odd-stage shift register 11 is connected to the first signal line CLK1, and the first clock signal terminal CK1 of the even-stage shift register 11 is connected to the third signal line CLK3.

The first clock signal SCK1 transmitted on the first signal line CLK1 and the fourth clock signal SCK1B transmitted on the second signal line CLK2 are inverse signals of each other. The second clock signal SCK2B transmitted on the fourth signal line CLK4 and the third clock signal SCK2 transmitted on the third signal line CLK3 are inverse signals of each other. By configuring the timing of each clock signal, stable output of the first gate driving signal SCAN1 and the second gate driving signal SCAN2 can be achieved.

In one embodiment, the first signal line CLK1, the second signal line CLK2, the third signal line CLK3, and the fourth signal line CLK4 may be respectively connected to different pins of a driving chip to output different clock signals.

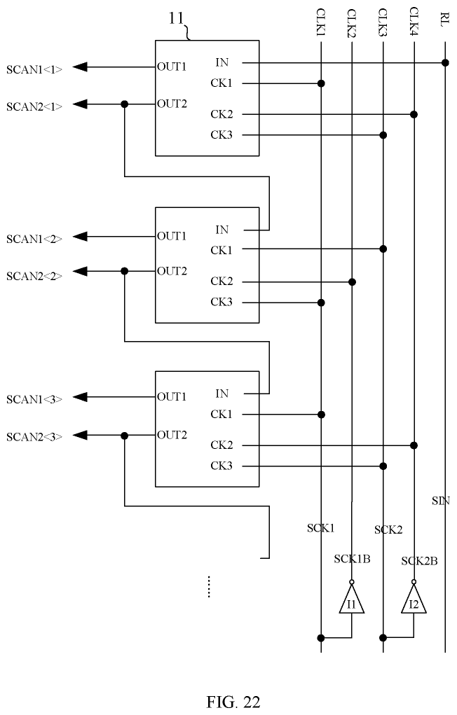

FIG. 22 is a schematic structural diagram of a gate driving circuit provided in an embodiment of the present disclosure. The display panel further includes a first inverter I1 and a second inverter I2. The first signal line CLK1 and the third signal line CLK3 are respectively connected to different pins of the driving chip. The second signal line CLK2 is connected to the first signal line CLK1 via the first inverter I1, and the fourth signal line CLK4 is connected to the third signal line CLK3 via the second inverter I2, which helps reduce the number of pins of the driving chip and optimize the connection resources of the driving chip, thereby further reducing the power consumption of the driving chip.

The display panel further includes a first inverter I1. The first signal line CLK1 and the third signal line CLK3 are respectively connected to different pins of the driving chip. The second signal line CLK2 is connected to the first signal line CLK1, and the fourth signal line CLK4 is connected to the third signal line CLK3. The first inverter I1 is connected between the second control terminal of the input module 150 in the shift register 11 and the second clock signal terminal CK2 of the shift register 11. The first inverter I1 is integrated inside the shift register 11. In one embodiment, the first signal line CLK1 can be used to multiplex the second signal line CLK2, and the third signal line CLK3 can be used to multiplex the fourth signal line CLK4, thereby saving the number of the second signal line CLK2 and the fourth signal line CLK4, which is beneficial for improving PPI.

In this embodiment, the display panel can be applied to a mobile phone, and can also be applied to any electronic product with a display function, including but not limited to the following categories: televisions, notebook computers, desktop monitors, tablet computers, digital cameras, smart bracelets, smart glasses, vehicle-mounted displays, medical devices, industrial control devices, touch interaction terminals, etc., which are not specifically limited in the embodiments of the present disclosure.

1. A shift register, comprising:
a first signal output module and a second signal output module,
a control terminal of the first signal output module and a first control terminal of the second signal output module are connected at a first node, the first node is configured to receive a start signal;
a second control terminal of the second signal output module and an output terminal of the first signal output module are connected at a second node, and the first signal output module is configured to output a first gate driving signal to the second node based on a voltage of the first node,
a second signal output module, wherein the second signal output module is configured to output a second gate driving signal based on the voltage of the first node and a voltage of the second node,
wherein a short pulse width level of the first gate driving signal is opposite to a short pulse width level of the second gate driving signal.

2. The shift register according to claim 1, wherein a first input terminal of the first signal output module receives a first voltage signal, a second input terminal of the first signal output module receives a second voltage signal, the first signal output module is configured to respond to the voltage of the first node and output the first voltage signal or the second voltage signal to the second node, and the first signal output module outputs the first gate driving signal.

3. The shift register according to claim 1, wherein a first input terminal of the second signal output module receives a first voltage signal, a second input terminal of the second signal output module receives a first clock signal, the second signal output module is configured to respond to the voltage of the first node and the voltage of the second node and output the first voltage signal or the first clock signal, and the second signal output module outputs the second gate driving signal.

4. The shift register according to claim 3, wherein the second signal output module comprises a coupling unit, the coupling unit is connected between a third node and the second control terminal of the second signal output module, and the coupling unit is configured to couple a potential of the second control terminal of the second signal output module.

5. The shift register according to claim 1, wherein the shift register comprises a first potential control module, a first control terminal of the first potential control module is connected to the second node, a second control terminal of the first potential control module receives a voltage control signal, an input terminal of the first potential control module receives a first voltage signal, an output terminal of the first potential control module is connected to the first node, and the first potential control module is configured to control the voltage of the first node based on the voltage of the second node and the voltage control signal.

6. The shift register according to claim 5, wherein a connection path between the first node and the first control terminal of the second signal output module comprises an auxiliary module, a first terminal of the auxiliary module is connected to the first node, a second terminal of the auxiliary module is connected to the first control terminal of the second signal output module, a control terminal of the auxiliary module receives a third voltage signal, and the auxiliary module is configured to prevent a voltage at the first control terminal of the second signal output module from being transmitted to the first node.

7. The shift register according to claim 5, wherein the shift register comprises an input module, a first control terminal of the input module receives a third clock signal, an input terminal of the input module receives the start signal, an output terminal of the input module is connected to the first node, and the input module is configured to transmit the start signal.

8. The shift register according to claim 7, wherein a first input terminal of the second signal output module receives a first voltage signal, and a second input terminal of the second signal output module receives a first clock signal;
the first clock signal, the second clock signal, and the third clock signal each comprise alternately arranged first level pulses and second level pulses;
a time duration of a second level pulse of the third clock signal covers a time duration of a first level pulse of the first clock signal.

9. The shift register according to claim 8, wherein a period of each of the first clock signal and the third clock signal is T, and a start time of a first occurrence of a first level pulse of the first clock signal differs from a start time of a first occurrence of a first level pulse of the third clock signal by T/2.

10. The shift register according to claim 8, wherein the second gate driving signal comprises at least one first level pulse.

11. The shift register according to claim 8, wherein the first gate driving signal comprises at least one second level pulse.

12. The shift register according to claim 2, wherein the second transistor is a vertical dual-gate transistor, the second transistor comprises a first gate and a second gate, and the first gate of the second transistor and a control electrode of the first transistor are both connected to the first node.

13. A shift register, comprising: a second signal output module, wherein a first control terminal of the second signal output module and an output terminal of a first potential control module are connected at a first node, the first node being configured to receive a start signal, and a second control terminal of the second signal output module and a first control terminal of the first potential control module are connected at a second node; a first potential control module, wherein the first potential control module is configured to control a voltage of the first node based on a voltage of the second node, and the second signal output module is configured to output a second gate driving signal based on the voltage of the first node and the voltage of the second node.

14. The shift register according to claim 13, wherein the first potential control module further comprises a second control terminal, the second control terminal of the first potential control module being configured to receive a voltage control signal; a first input terminal of the second signal output module is configured to receive a first voltage signal, a second input terminal of the second signal output module is configured to receive a first clock signal, and the second signal output module is configured to output the first voltage signal or the first clock signal in response to the voltage of the first node and the voltage of the second node, so as to output the second gate driving signal.

15. The shift register according to claim 13, wherein the shift register comprises a first signal output module, an output terminal of the first signal output module being connected to the second node, a control terminal of the first signal output module being connected to the first node, and the first signal output module being configured to output a first gate driving signal to the second node based on the voltage of the first node, wherein a short pulse width level of the first gate driving signal is opposite to a short pulse width level of the second gate driving signal.

16. The shift register according to claim 15, wherein a connection path between the first node and the first control terminal of the second signal output module comprises an auxiliary module, a first terminal of the auxiliary module being connected to the first node, a second terminal of the auxiliary module being connected to the first control terminal of the second signal output module, a control terminal of the auxiliary module being configured to receive a third voltage signal, and the auxiliary module being configured to prevent the voltage of the first control terminal of the second signal output module from being transmitted to the first node.

17. The shift register according to claim 14, wherein the shift register comprises an input module, a first control terminal of the input module being configured to receive a third clock signal, an input terminal of the input module being configured to receive the start signal, an output terminal of the input module being connected to the first node, and the input module being configured to transmit the start signal.

18. The shift register according to claim 15, wherein the first signal output module comprises a first transistor and a second transistor, a control electrode of the first transistor and a control electrode of the second transistor are both connected to the first node, a first electrode of the first transistor is configured to receive the first voltage signal, a second electrode of the first transistor and a second electrode of the second transistor are both connected to the second node, and a first electrode of the second transistor is configured to receive a second voltage signal.

19. A display panel, comprising: a gate driving circuit, wherein the gate driving circuit comprises a plurality of shift registers according to claim 1, the plurality of shift registers being connected in cascade; among the plurality of cascaded shift registers, the start signal received by a next-stage shift register is provided by an output terminal of the second signal output module of a current-stage shift register, wherein the start signal of a first-stage shift register is provided by a trigger signal line.

20. The display panel according to claim 19, wherein the shift register comprises an input terminal, a first clock signal terminal, a second clock signal terminal, a third clock signal terminal, a first output terminal, and a second output terminal, and the input terminal of the next-stage shift register is connected to the second output terminal of the current-stage shift register; wherein the shift register comprises a first potential control module and an input module, the input terminal of the input module serving as the input terminal of the shift register, the output terminal of the first signal output module serving as the first output terminal of the shift register, the output terminal of the second signal output module serving as the second output terminal of the shift register, the second input terminal of the second signal output module serving as the first clock signal terminal of the shift register, the second control terminal of the input module serving as the second clock signal terminal of the shift register, and the first control terminal of the input module serving as the third clock signal terminal of the shift register.
